(19) United States
(12) Patent Application Publication
(10) Pub. No.: US 2025/0238583 A1
(43) Pub. Date: Jul. 24, 2025

(54) MODELING A HYDROCARBON RESERVOIR

(71) Applicant: Saudi Arabian Oil Company, Dhahran (SA)

(72) Inventors: Oshokhayamhe IIamah, Dhahran (SA); Rayan Alidi, Dhahran (SA)

(21) Appl. No.: 18/418,677

(22) Filed: Jan. 22, 2024

(51) Int. Cl. G06F 30/28; E21B 43/26; G01V 20/00

(52) U.S. Cl. CPC G06F 30/28; G01V 20/00; E21B 43/26; E21B 2200/20

(57) ABSTRACT

Techniques for modeling a reservoir include identifying or inputting well and reservoir model parameters into a control system; calculating, with the control system, one or more hydraulic fracture limits of one or more hydraulic fractures in the reservoir model; determining, with the control system, one or more fracture segments; performing, with the control system, connection calculations based on the one or more hydraulic fracture limits and one or more fracture segments; setting up, with the control system, connections between the one or more hydraulic fractures and a matrix grid of the reservoir model; performing, with the control system, a reservoir simulation; and outputting, with the control system, reservoir simulation data from the reservoir simulation.

### TECHNICAL FIELD

The present disclosure describes systems and methods for field-scale hydraulic fracture modeling in a reservoir simulation and, more particularly, field-scale hydraulic fracture modeling in a complex corner-point reservoir simulation grid.

### BACKGROUND

An embedded discrete fracture modeling (EDFM) technique is a conceptually sound approach for efficiently modelling hydraulic fractures. However, in practice, its use is severely limited due to the difficulty inherent in reliable EDFM preprocessing of complex three-dimensional (3D) corner-point grids of the kind that are typically encountered in reservoir engineering practice. To obtain a reliable EDFM pre-processor that can be widely used in practice, efficient methods for determining fracture-grid intersections for general/complex simulation grids must by formulated and implemented. Furthermore, methods that simplify the input of hydraulic fracture descriptions, for all kinds of hydraulic fractures, into the EDFM pre-processor and that permit easy activation, deactivation, and visualization of the hydraulic fractures must be devised.

### SUMMARY

In an example implementation, a computer-implemented method of modeling a reservoir includes identifying or inputting well and reservoir model parameters into a control system; calculating, with the control system, one or more hydraulic fracture limits of one or more hydraulic fractures in the reservoir model; determining, with the control system, one or more fracture segments; performing, with the control system, connection calculations based on the one or more hydraulic fracture limits and one or more fracture segments; setting up, with the control system, connections between the one or more hydraulic fractures and a matrix grid of the reservoir model; performing, with the control system, a reservoir simulation; and outputting, with the control system, reservoir simulation data from the reservoir simulation.

In an aspect combinable with the example implementation, the reservoir model includes an embedded discrete fracture modeling (EDFM) reservoir model that includes a matrix computational domain, a spare mirror fracture computational domain, and an inactive zone that separates the matrix computational domain and the spare mirror fracture computational domain.

In another aspect combinable with any of the previous aspects, calculating the one or more hydraulic fracture limits of one or more hydraulic fractures in the reservoir model includes calculating, for each hydraulic fracture, a fracture surface limit and a fracture wing adjustment based on the well and reservoir model parameters including well trajectory information and fracture geometry information.

In another aspect combinable with any of the previous aspects, determining the one or more fracture segments includes executing, with the control system, a multi algorithmic framework.

In another aspect combinable with any of the previous aspects, executing the multi algorithmic framework includes executing, with the control system, a first algorithm to determine a fracture segments processing framework; executing, with the control system, a second algorithm to determine fracture segments; and executing, with the control system, a third algorithm to determine fracture segment adjacency and common perimeter determination.

In another aspect combinable with any of the previous aspects, performing the connection calculations includes executing, with the control system, a fourth algorithm to determine a numerical estimation of one or more average normal distances between a fracture segment and a connected matrix gridcell of the reservoir model; and executing, with the control system, a fifth algorithm to determine one or more fracture type connection transmissibility factors.

In another aspect combinable with any of the previous aspects, performing the reservoir simulation includes determining, with the control system, hydrocarbon fluid production rate and well bottom hole pressure for each well in the reservoir model.

In another example implementation, a computing system includes one or more memory modules configured to store well and reservoir model parameters; one or more hardware processors communicably coupled to the one or more memory modules and configured to execute instructions stored on the one or more memory modules to perform operations. The operations include calculating one or more hydraulic fracture limits of one or more hydraulic fractures in the reservoir model; determining one or more fracture segments; performing connection calculations based on the one or more hydraulic fracture limits and one or more fracture segments; setting up connections between the one or more hydraulic fractures and a matrix grid of the reservoir model; performing a reservoir simulation; and outputting reservoir simulation data from the reservoir simulation.

In an aspect combinable with the example implementation, the reservoir model includes an embedded discrete fracture modeling (EDFM) reservoir model that includes a matrix computational domain, a spare mirror fracture computational domain, and an inactive zone that separates the matrix computational domain and the spare mirror fracture computational domain.

In another aspect combinable with any of the previous aspects, the operation of calculating the one or more hydraulic fracture limits of one or more hydraulic fractures in the reservoir model includes calculating, for each hydraulic fracture, a fracture surface limit and a fracture wing adjustment based on the well and reservoir model parameters including well trajectory information and fracture geometry information.

In another aspect combinable with any of the previous aspects, the operation of determining the one or more fracture segments includes executing a multi algorithmic framework.

In another aspect combinable with any of the previous aspects, the operation of executing the multi algorithmic framework includes executing a first algorithm to determine a fracture segments processing framework; executing a second algorithm to determine fracture segments; and executing a third algorithm to determine fracture segment adjacency and common perimeter determination.

In another aspect combinable with any of the previous aspects, the operation of performing the connection calculations includes executing a fourth algorithm to determine a numerical estimation of one or more average normal distances between a fracture segment and a connected matrix gridcell of the reservoir model; and executing a fifth algorithm to determine one or more fracture type connection transmissibility factors.

In another aspect combinable with any of the previous aspects, the operation of performing the reservoir simulation includes determining hydrocarbon fluid production rate and well bottom hole pressure for each well in the reservoir model.

In another example implementation, an apparatus including a tangible, non-transitory computer readable memory including instructions for causing one or more processors to perform operations including identifying well and reservoir model parameters; calculating one or more hydraulic fracture limits of one or more hydraulic fractures in the reservoir model; determining one or more fracture segments; performing connection calculations based on the one or more hydraulic fracture limits and one or more fracture segments; setting up connections between the one or more hydraulic fractures and a matrix grid of the reservoir model; performing a reservoir simulation; and outputting reservoir simulation data from the reservoir simulation.

In an aspect combinable with the example implementation, the reservoir model includes an embedded discrete fracture modeling (EDFM) reservoir model that includes a matrix computational domain, a spare mirror fracture computational domain, and an inactive zone that separates the matrix computational domain and the spare mirror fracture computational domain.

In another aspect combinable with any of the previous aspects, the operation of calculating the one or more hydraulic fracture limits of one or more hydraulic fractures in the reservoir model includes calculating, for each hydraulic fracture, a fracture surface limit and a fracture wing adjustment based on the well and reservoir model parameters including well trajectory information and fracture geometry information.

In another aspect combinable with any of the previous aspects, the operation of determining the one or more fracture segments includes executing a multi algorithmic framework.

In another aspect combinable with any of the previous aspects, the operation of executing the multi algorithmic framework includes executing a first algorithm to determine a fracture segments processing framework; executing a second algorithm to determine fracture segments; and executing a third algorithm to determine fracture segment adjacency and common perimeter determination.

In another aspect combinable with any of the previous aspects, the operation of performing the connection calculations includes executing a fourth algorithm to determine a numerical estimation of one or more average normal distances between a fracture segment and a connected matrix gridcell of the reservoir model; and executing a fifth algorithm to determine one or more fracture type connection transmissibility factors.

In another aspect combinable with any of the previous aspects, the operation of performing the reservoir simulation includes determining hydrocarbon fluid production rate and well bottom hole pressure for each well in the reservoir model.

Implementations of systems and methods according to the present disclosure can include one, some, or all of the following features. For example, implementations according to the present disclosure can allow parameterization, input and modelling of hydraulic fractures of all types. As another example, implementations according to the present disclosure can allow more realistic hydraulic fracture representations, including support for non-symmetrical and curved fracture outline representations as well as symmetric fractures with straight edges. As another example, implementations according to the present disclosure can allow easy activation and/or deactivation of one or more of the modelled hydraulic fractures, as needed, during the course of reservoir simulation. As another example, implementations according to the present disclosure can allow more intuitive 3D visualization of the hydraulic fracture reservoir simulation results. As another example, implementations according to the present disclosure can allow more computationally efficient field-scale simulation of reservoirs with hydraulically fractured wells, compared to local grid refinement methods.

The details of one or more implementations of the subject matter described in this disclosure are set forth in the accompanying drawings and the description below. Other features, aspects, and advantages of the subject matter will become apparent from the description, the drawings, and the claims.

### BRIEF DESCRIPTION OF THE DRAWINGS

FIG. 1 is a schematic illustration of a hydrocarbon reservoir with one or more hydraulically fractured wellbores according to the present disclosure.

FIG. 2 is a flowchart that illustrates an example workflow method according to the present disclosure.

FIGS. 3A and 3B are schematic illustrations of models of a reservoir with hydraulically fractured wells according to the present disclosure.

FIG. 4 is a schematic illustration of a conventional EDFM model layout.

FIGS. 5A-5D are schematic illustrations of a geometry parameterization for longitudinal fractures according to the present disclosure.

FIGS. 6A-6C are schematic illustrations of a geometry parameterization for transverse fractures according to the present disclosure.

FIGS. 7A and 7B are schematic illustrations of fracture surface limit control points and associated fracture extremities points as well as a data structure used to hold fracture extremities points according to the present disclosure.

FIG. 8A is a schematic illustration of an ellipse constructed to according to the de La Hire method to model a hydraulic fracture according to the present disclosure.

FIG. 8B is a schematic illustration of a straight symmetric fracture outline and a more realistic curved fracture outline for a longitudinal vertical fracture orientation according to the present disclosure.

FIG. 8C is a schematic illustration that shows calculation of elliptical fracture outline points for each control point based on provided fracture wing height and width according to the present disclosure.

FIG. 9 is a schematic illustration that shows a 2D vertical section along a fracture plane that shows an elliptical fracture and cross-section of grid cells intersected by the fracture plane according to the present disclosure.

FIGS. 10A and 10B are schematic illustrations of fracture segment perimeter coordinates for grid cells defined by anchor points according to the present disclosure.

FIG. 10C illustrates a portion of pseudo-code according to the present disclosure.

FIG. 11 is a schematic illustration that shows bounding polygons of two fracture segments according to the present disclosure.

FIGS. 12A-12C are schematic illustrations of possible grid cell and corresponding fracture segments adjacency scenarios according to the present disclosure.

FIG. 13 illustrates a portion of pseudo-code according to the present disclosure.

FIG. 14 illustrates another portion of pseudo-code according to the present disclosure.

FIG. 15 illustrates another portion of pseudo-code according to the present disclosure.

FIG. 16 is a schematic illustration of a model that shows a homogeneous tight gas reservoir with one fully penetrating vertical well with a bi-wing fracture in a first example reservoir simulation according to the present disclosure.

FIGS. 17A and 17B are graphs that show well gas rate and bottom hole flowing pressures in the first example reservoir simulation according to the present disclosure.

FIG. 18 is a schematic illustration of a model that shows a homogeneous tight gas reservoir with one horizontal multistage fracture well in a second example reservoir simulation according to the present disclosure.

FIGS. 19A and 19B are graphs that show well gas rate and bottom hole flowing pressures in the second example reservoir simulation according to the present disclosure.

FIG. 20 is a schematic illustration of a model that shows a heterogeneous tight gas reservoir with multiple wells having different types of fractures in a complex corner-point simulation grid in a third example reservoir simulation according to the present disclosure.

FIG. 21 is a graph that shows a gas rate profile imposed on each of the active five wells in the third example reservoir simulation according to the present disclosure.

FIGS. 22A-22E are illustrations of 2D maps and graphs that show bottom hole flowing pressures of the wells in the third example reservoir simulation according to the present disclosure.

FIGS. 23A and 23B are graphs that show reservoir simulation time comparisons between various simulation methods according to the present disclosure.

FIG. 24 shows a schematic drawing of a control system that can be used to perform a reservoir simulation according to the present disclosure.

### DETAILED DESCRIPTION

The present disclosure describes implementations of computer-implemented systems, apparatus, and methods that implement an embedded discrete fracture model augmented grid layout through standardized and simplified algorithms necessary to efficiently and reliably pre-process the model. Example implementations further include development of an 8-factor generalized hydraulic fracture parameterization and wing adjustment scheme to simplify and standardize description of hydraulic fractures of all types and to facilitate their input into the hydraulic fracture modeling algorithms. In some aspects, implementations further include development and implementation of robust algorithms capable of determining fracture-grid intersections, fracture segments, and associated connection transmissibility factors in complex 3D corner-point reservoir simulation grids. This also includes development of techniques to effectively activate or deactivate an embedded hydraulic fracture, as needed, during the course of a reservoir simulation.

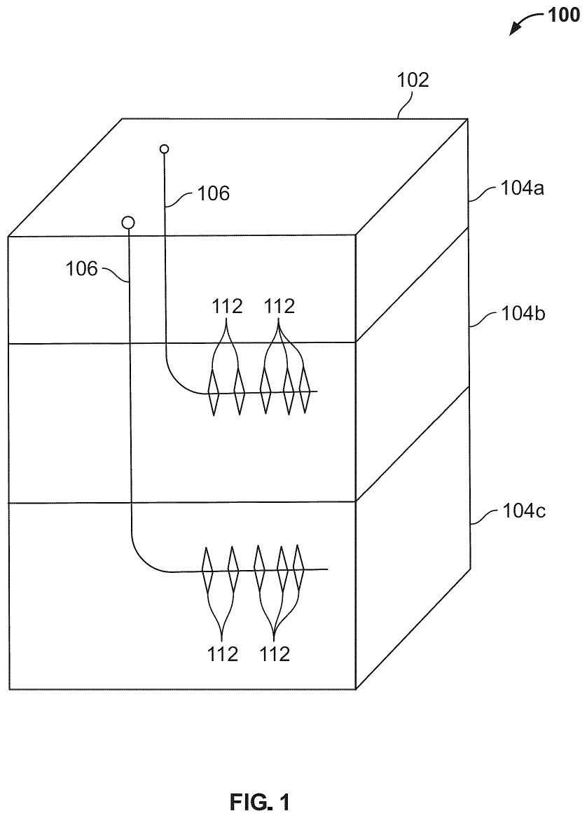

FIG. 1 is a schematic illustration of a hydrocarbon reservoir 100 with one or more hydraulically fractured wellbores 106 according to the present disclosure. As conventionally known, hydrocarbon reservoir 100 can include one or more subterranean formations 104a-104c through which the one or more wellbores 106 are formed from a terranean surface 102 (including subsea terranean surfaces). The wellbores 106 include hydraulic fractures 112, which, in this example, are formed from a horizontal portion of the wellbores 106. However, other example implementations of hydrocarbon reservoirs 100 include (alternatively or additionally) one or more vertical or slant wellbores with hydraulic fractures.

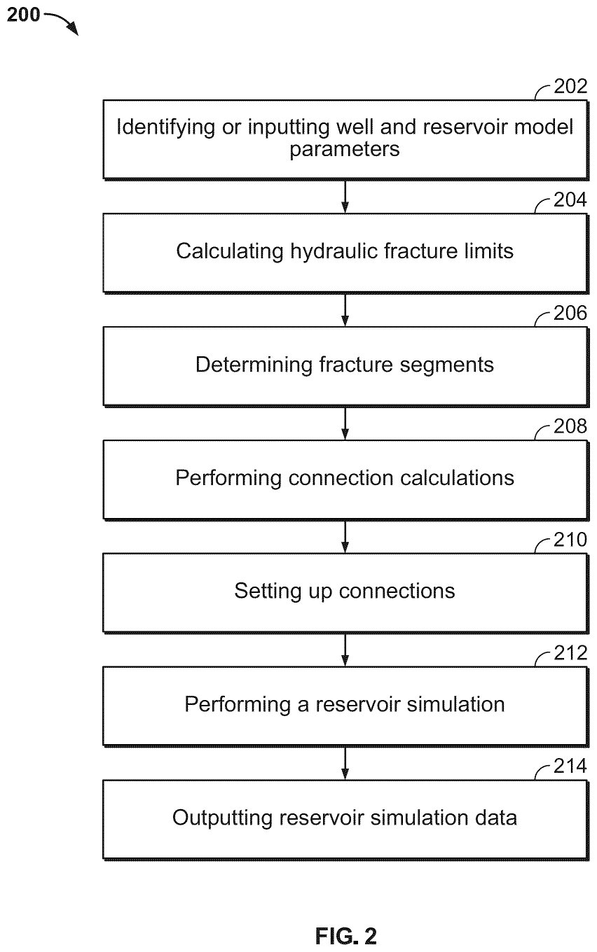

FIG. 2 is a flowchart that illustrates an example workflow method 200 according to the present disclosure. Method 200 can be implemented in computer-implemented systems, apparatus, and methods that execute a reservoir simulation using an embedded discrete fracture model (EDFM) augmented grid layout. Method 200 can begin at step 202, which includes identifying or inputting well and reservoir model parameters.

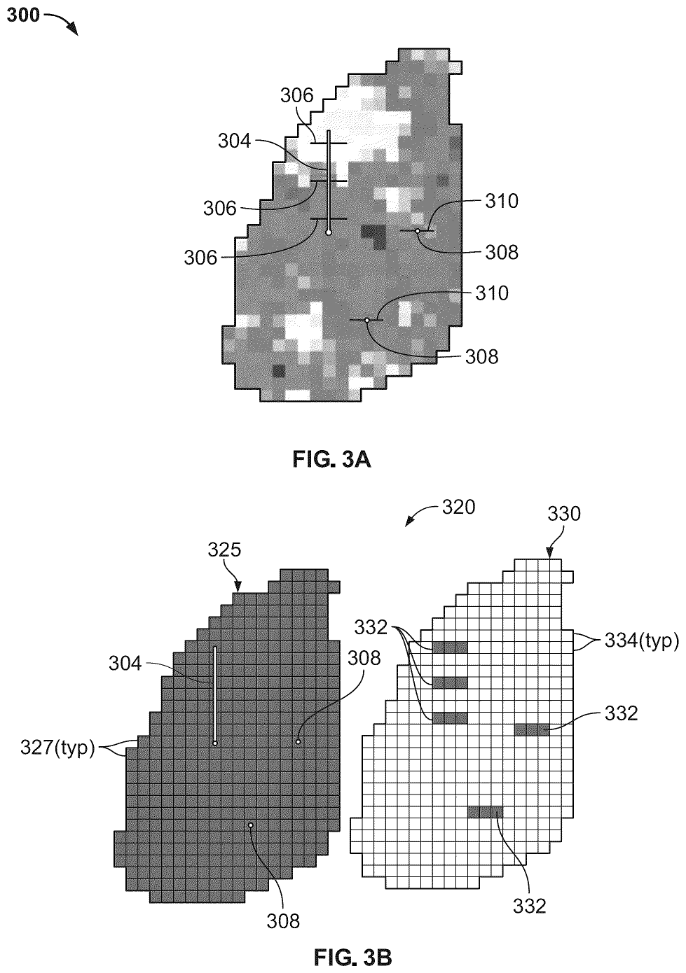

For example, in step 202 and the disclosed EDFM approach, two computational domains can be used. A first domain can be for the matrix of the reservoir, and a second domain can be for the hydraulic fractures formed in the reservoir. For the fracture domain, a “sparse mirror” fracture grid that is a horizontally offset mirror image of the matrix grid can be used. In this sparse mirror fracture grid, reservoir cells that are not intersected by the fractures are permanently deactivated. FIG. 3A shows an example adaptation of the PUNQ-S3 reservoir model 300 including directional well 304 with hydraulic fractures 306 and vertical wells 308 with hydraulic fractures 310. FIG. 3B shows the corresponding EDFM model 320 according to the present disclosure.

The EDFM model 320 is comprised of three parts. A first part is a matrix computational domain 325. A second part is a fracture computational domain 330. A third part is an inactive zone, separating the two aforementioned computational domains 325 and 330. The matrix computational domain 325 includes the wells 304 and 308 from the reservoir model 300, as well as active matrix grid cells 327. However, the matrix computational domain 325 does not explicitly include hydraulic fractures 306 and 310. The fracture computational domain 330 is the sparse mirror fracture grid that exactly mirrors the matrix grid (of domain 325) dimensionally and structurally. In the fracture computational domain 330, only cells 332 that are intersected by the hydraulic fractures 306 and 310 are active while all other cells 334 are inactive.

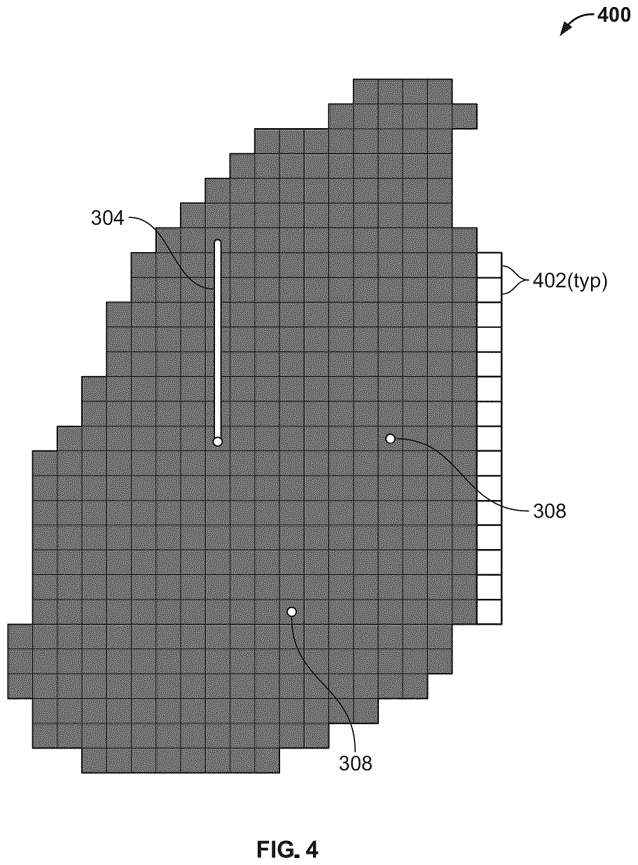

The EDFM model 320 provides one or more advantages. First, given that the fracture grid (domain 330) has the exact same dimensions and structural form as the matrix grid (domain 325) and that the fracture cells 332 are located, relatively, in the same location as the actual fracture(s) (306 and 310) in the reservoir, spatial influences on the hydraulic fractures are implicitly captured. For example, if the well location and fracture geometry are such that the fracture intersects a water zone, this is implicitly reflected in the EDFM model 320. In some aspects, this is an important practical improvement over existing conventional EDFM formulations, in which the fracture cells are simply appended to one arbitrarily selected side of the matrix grid as shown in FIG. 4. Indeed, the conventional EDFM model 400 includes fracture cells 402 that are appended to one arbitrarily selected side of the matrix grid.

Second, because the fracture cells 332 are placed in their actual relative location within the computational domain, 3D visualization of the hydraulic fracture reservoir simulation results is far more intuitive. This can be an important practical improvement over conventional EDFM models (like model 400).

Third, in some aspects, standardizing the EDFM layout can simplify the algorithmic formulations since the EDFM layout is no longer arbitrary and is known upfront. Although the EDFM model 320 requires new specialized EDFM pre-processing algorithms, it does not introduce any discernable runtime computational overheads, compared to the conventional EDFM model 400, since most of the cells in the fracture computational domain are inactive. To obtain a final EDFM simulation model, the matrix and fracture computational domains are numerically coupled by means of non-neighbor and well connection factors as described herein.

Step 202 also includes identifying or inputting a generalized hydraulic fracture parameterization. For example, in order to model a hydraulic fracture, the orientation and extent of the fracture in 3D space must be described. In example implementations, an 8-factor hydraulic fracture parameterization scheme can be used with the following parameters:

Type—fracture type can be either LV, LD or TD, where L and T corresponds to longitudinal and transverse fractures, and V and D corresponds to vertical and deviated wellbores.

Outline—fracture outline can be STRAIGHT or ELLIPTICAL to describe the outline of the fracture extremities. STRAIGHT indicates straight fractured edges while ELLIPTICAL indicates curved edges.

Reference MD (refMD)—fracture measured depth of the reference point on the well lateral trajectory. All other fracture geometry parameters are specified with respect to this reference point.

Azimuth (α)—fracture azimuth is the angle on the horizontal plane, which the always vertical fracture plane makes in a counterclockwise sense with the positive horizontal x-axis. This parameter may be used for cases in which the projection of the fracture on the horizontal plane is not entirely straddled by the projection of the lateral trajectory to the horizontal plane. This parameter is used for (i) LV—longitudinal fracture on vertical well and (ii) TD—transverse fracture on deviated/horizontal well but not for LD—longitudinal fracture on deviated/horizontal well

Wing heights (wh₁ and wh₂)—fracture wing height is, with respect to the reference point, the height of the fracture wing measured along the wellbore, on the fracture plane.

Wing widths (ww₁ and ww₂)—fracture wing width is, with respect to the reference point, the width of the fracture wings measured normal to the wellbore, on the fracture plane.

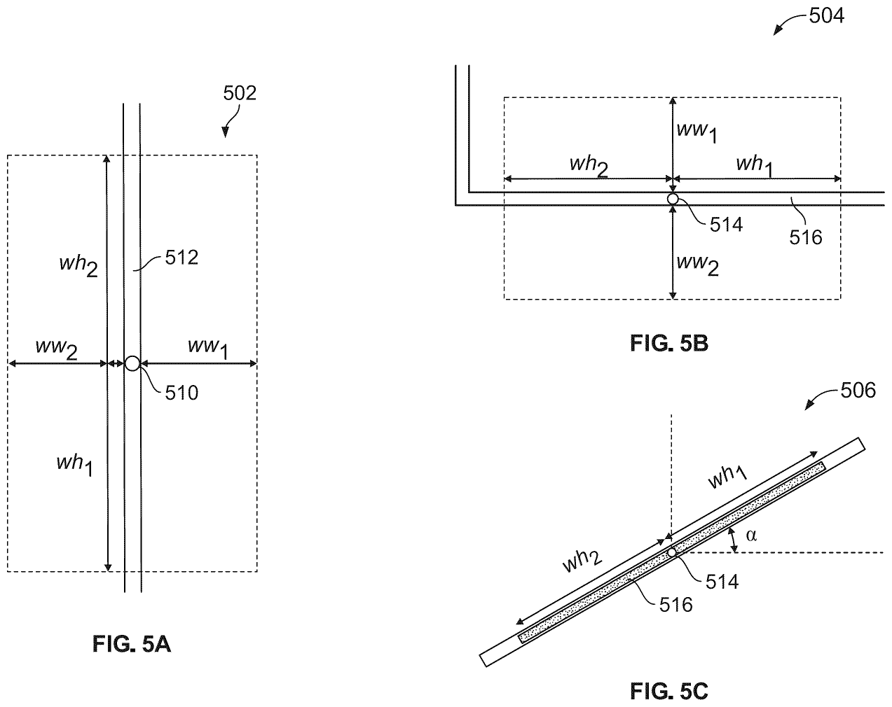

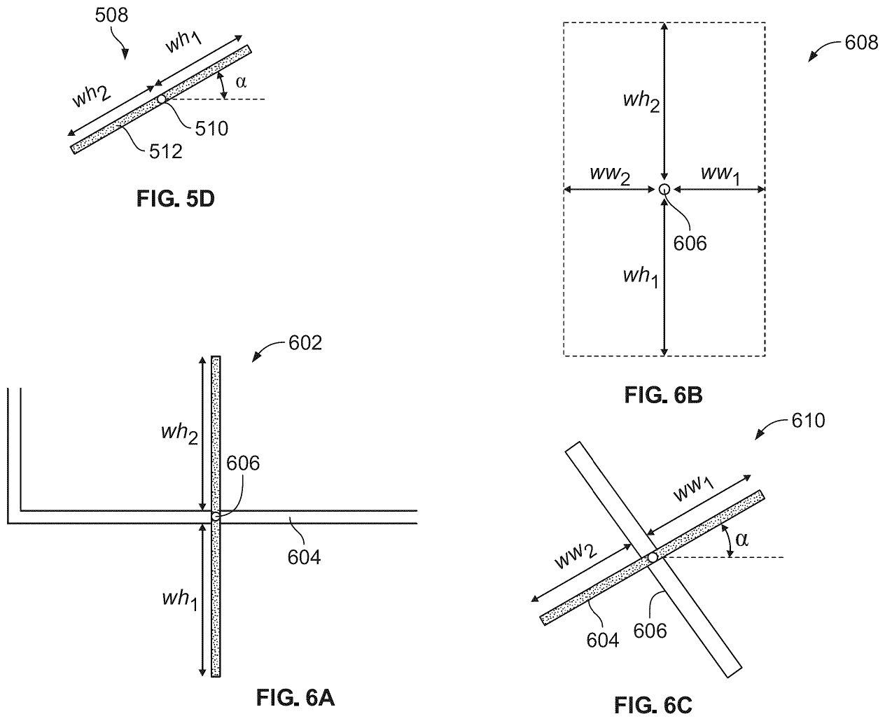

Turning briefly to FIGS. 5A-5D, these figures are schematic illustrations of a geometry parameterization for longitudinal fractures according to the present disclosure. View 502 is a view normal to a fracture plane for an LV fracture 512 that emanates from wellbore 510. View 504 is a view normal to a fracture plane for an LD fracture 516 that emanates from wellbore 514. View 506 is a plan view of LD fracture 516 that emanates from wellbore 514. View 508 is a plan view of LV fracture 512 that emanates from wellbore 510.

FIGS. 6A-6C are schematic illustrations of a geometry parameterization for transverse fractures according to the present disclosure. View 602 is a side view of a TD fracture 604 that emanates from wellbore 606. View 608 is a view normal to a fracture plane for the TD fracture 604 that emanates from wellbore 606. View 610 is a plan view of TD fracture 604 that emanates from wellbore 606.

In some aspects, in order to fully describe a hydraulic fracture, other variables (for example, fracture aperture widths, fracture conductivity, stage number, activation dates, etc.) may be required. The input fracture geometry data, together with associated well trajectory information and the original reservoir model grid may be required to generate the EDFM model 320 of a reservoir with hydraulically fractured wells. Thus, method 200 can continue at step 204, which includes calculating hydraulic fracture limits.

For example, step 204 can also include calculating hydraulic fracture limits by identifying or inputting well trajectory information and fracture geometry information and then determining the fracture surface limit. For example, for each fracture entry, an associated lateral trajectory data is found by obtaining x, y, z coordinates of the reference point by using the refMD as a query key against the provided MD data to obtain the corresponding x, y and z trajectory data values.

If the fracture is longitudinal, then this process is as follows:
1. Get the fracture start and stop MD as:

$$\begin{matrix}startMD = refMD - {wh}_{2} , \\ stopMD = refMD - {wh}_{2} .\end{matrix}$$

2. Resample the fracture MD range (startMD to stopMD) to obtain more granular trajectory control points for MD, x, y and z (in other words, TVDSS).
3. For each control point obtained from the above,
(i) Get x, y, z; referred to as tₓ, t_{y} and t_{z},
(ii) If the lateral is reported as vertical (an LV type code), the left- and right-wing extremities of the fracture surface are computed as:

$$\begin{matrix}{x}_{1} = {t}_{x} - A w {w}_{2} cos α \\ {y}_{1} = {t}_{y} - A w {w}_{2} sin α \\ {z}_{1} = {t}_{z} \\ {x}_{r} = {t}_{x} - A w {w}_{1} cos α \\ {y}_{r} = {t}_{y} - A w {w}_{1} sin α \\ {z}_{r} = {t}_{z} .\end{matrix}$$

(iii) If the lateral is reported as deviated (an LD type code), the upper and lower wing extremities of the fracture surface are computed as:

$$\begin{matrix}{x}_{u} = {t}_{x} \\ {y}_{u} = {t}_{y} \\ {z}_{u} = {t}_{z} - A w {w}_{1} \\ {x}_{1} = {t}_{x} \\ {y}_{1} = {t}_{y} \\ {z}_{1} = {t}_{z} + A w {w}_{2} .\end{matrix}$$

In some aspects, the LD approach is indifferent to whether the lateral is strictly horizontal or simply subvertical.

If the fracture is longitudinal, then this process is as follows:
1. Since it is known or assumed that the fracture is always vertical, the max and min z on the fracture surface can be established as:

$$\begin{matrix}f {z}_{min} = refTVDSS - {wh}_{2} \\ f {z}_{max} = refTVDSS + {wh}_{1} .\end{matrix}$$

2. ‘N’ evenly spaced z values spanning the above max/min limit can be generated as:

$$ControlPoints = linspace ( f {z}_{min} , {fz}_{max} , N ) .$$

3. For each control point obtained from the above, determine the left and right wing extremities of the fracture surface as:

$$\begin{matrix}{x}_{1} = {x}_{ref} - {Aww}_{2} cos α \\ {y}_{1} = {y}_{ref} - {Aww}_{2} sin α \\ {z}_{1} = z \\ {x}_{r} = {x}_{ref} + {Aww}_{1} cos α \\ {y}_{r} = {y}_{ref} + {Aww}_{1} sin α \\ {z}_{r} = z .\end{matrix}$$

In all of the above cases (LV, TD and LD), Aww₁ and Aww₂ refer to the respective adjusted wing widths, which account for the specified fracture outline as described herein with respect to the fracture wing adjustment calculations.

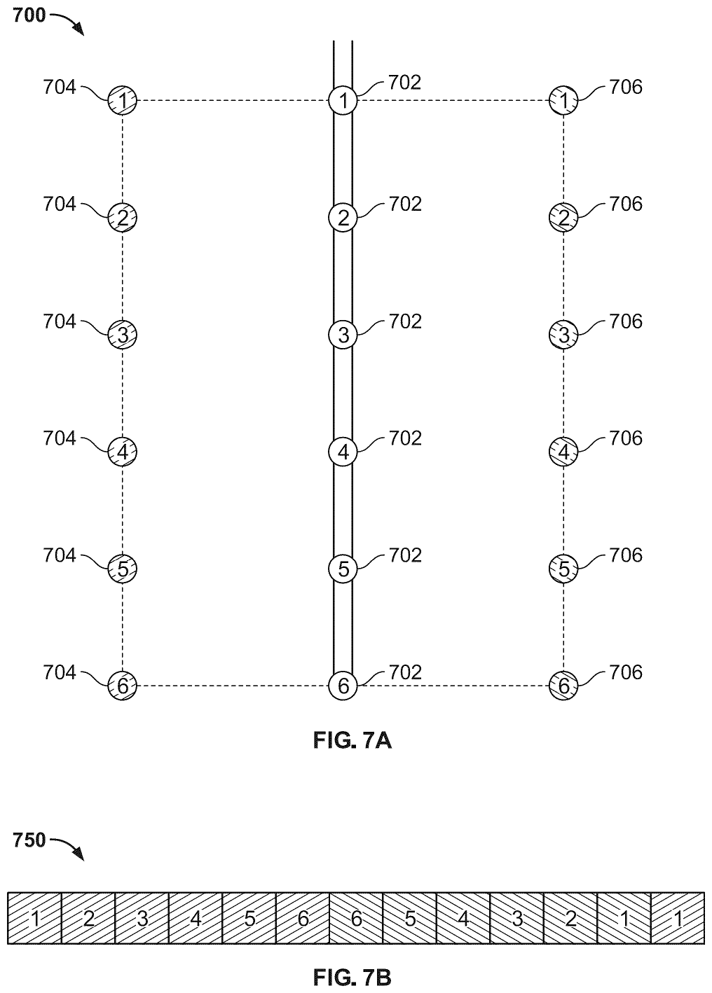

The fracture extremities calculated for each control point can stored in a point array, such that traversing this point array corresponds to traversing the polygon describing the fracture surface limit/outline. For example, as shown in FIG. 7A, graphic 700 includes control points 702 and associated fracture extremities: min points 704 and max points 706. Data structure 750 can be used to hold the associated fracture extremity points 704 and 706 (in other words, the surface limit points).

If N is the number of control points, then the required array size for data structure 750 is 2N+1. The last array element holds identical point data as the first array element, mimicking a closed polygon. If the extremities points 704 are entered first in the structure 750 and Rᵢ and Lᵢ are the array indices of the left and right extremities for the it control/query point, then, for “1” based arrays (for example, MATLAB), Lᵢ=i and Rᵢ=2N+1−i. Once the extremities are fully determined, the axis aligned bounding box (AABB) of the fracture limit polygon can be calculated for later use.

Step 204 can also include fracture wing adjustment calculations. For example, in reservoir simulation of hydraulically fractured wells, a symmetric bi-wing fracture with straight edges is usually assumed. In actual practice, the outline of a hydraulic fracture may seldom be symmetric and/or straight. As such, the hydraulic fracture parameterization approach of the present disclosure allows more realistic hydraulic fracture representations, including support for non-symmetrical and curved fracture outline representations. Indeed, method 200 still supports symmetric fractures with straight edges, as is usually assumed. However, curved fracture outlines based on an elliptical approximation can also be realized in step 204.

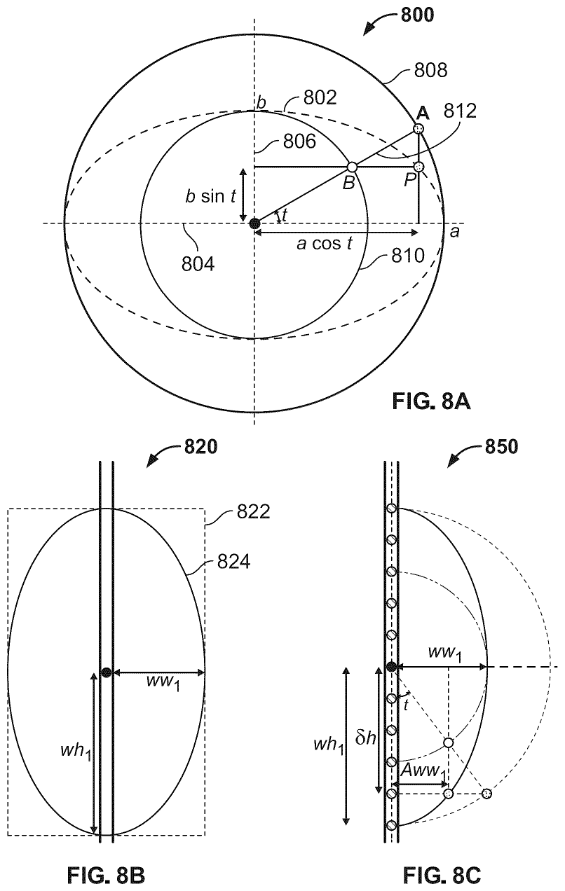

In FIG. 8A, graphic 800 includes an ellipse 802 with major diameter 804 of 2a and minor diameter 806 of 2b. According to de La Hire's method, ellipse 802 can be constructed from two concentric circles 808 and 810 of radii a and b, respectively, by drawing a line 812 at an angle t from the major axis, passing through both circles 808 and 810 at A and B respectively. The normals to axis a and b through points A and B respectively, intersect at point P which must line on the perimeter of the ellipse.

According to the present disclosure, this elliptical concept can be adapted to obtain hydraulic fracture representations with more realistic elliptical outlines as shown in FIGS. 8B and 8C. FIG. 8B shows a graphic 820 in which ww₁ and wh₁ define a straight symmetric fracture 822, while a more realistic curved fracture 824 is shown for an LV fracture orientation. For a more accurate representation, first, compute t for every control point as:

$$cos t = \frac{δ h}{w {h}_{1}} .$$

With t known, calculate Aww₁, the adjusted wing width, as Aww₁=ww₁ sin t. Once Aww₁ is determined, it is used instead of ww₁ in the wing calculation, avoiding straight fracture edges (ww₁ is fixed and would result in straight fracture edges whereas Aww₁ is variable and would result in elliptical fracture outline). In example implementations, ww₁=ww₂ and wh₁=wh₂ can be requirements. This is shown graphically in graphic 850 in FIG. 8C.

Method 200 can continue at step 206, which includes determining fracture segments. For example, once the polygon describing the surface limit of each fracture has been obtained as described with reference to step 204, the next step in method 200 is to determine with which active matrix gridcells the planar fracture surface intersects. These gridcells are referred to as fracture host matrix gridcells. Further, the perimeter coordinates of each fracture segment are determined (in other words, of the subarea of the planar fracture surface contained within each fracture host matrix gridcell). This determination can be achieved in a multi-algorithm approach as describe herein.

In the multi algorithmic approach, a set of hydraulic fracture representations is obtained in a first algorithm; this set is used as an input to a second algorithm for each active matrix gridcell representation. An example of the first algorithm is as follows:

1. Obtain the set {F} of all hydraulic fracture representations. Each fracture representation includes the fracture limit polygon vertices, associated axis-aligned bounding box and the fracture plane unit normal vector.

2. Obtain the set {G} of active matrix gridcell representations in the input grid. Each active matrix gridcell representation includes the gridcell vertices and associated axis-aligned bounding box.

3. For each active gridcell representation M in {G}, sequentially perform the second algorithm on each fracture representation until the first fracture intersecting the gridcell is encountered. If one of the fractures intersects with M, collect the fracture segment information obtained from the second algorithm grouped by fracture (for future use).

4. For all distinct fracture pairs in each group of fracture segments, execute a third algorithm to establish fracture segment adjacencies.

The second algorithm can include two parts in this example. The first part involves a fast check using the axis-aligned bounding boxes of the input matrix gridcell and fracture representations. If the axis-aligned bounding boxes do not overlap, the fracture does not intersect the matrix gridcell—so the second part of the second algorithm is skipped and the next fracture representation in the input dataset is considered. On the other hand, if the axis-aligned bounding boxes overlap, the second part of the second algorithm is executed.

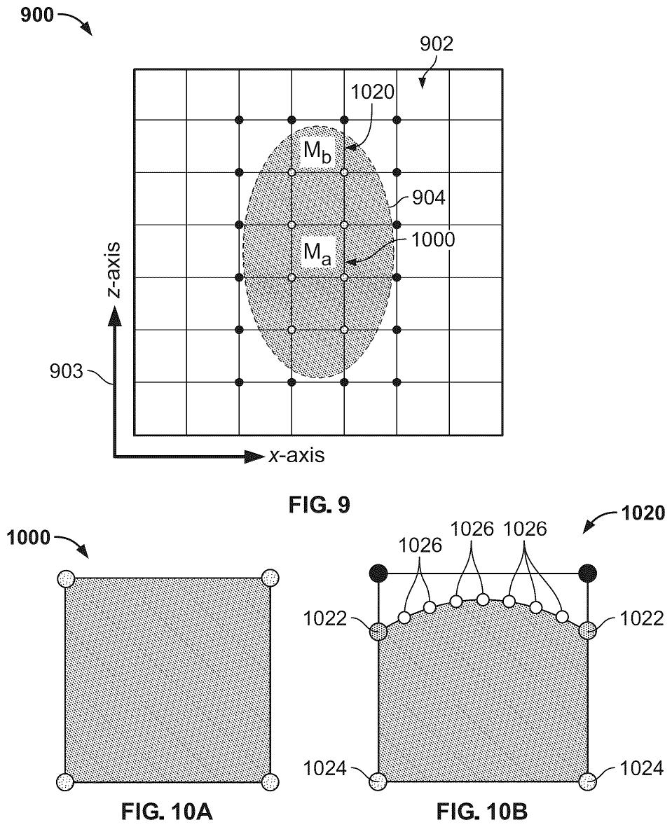

In the second part of the second algorithm, the fracture plane gridcell “anchor points” are determined. Anchor points are the points in 3D space at which the gridcell edges intersect the fracture plane. For example, FIG. 9 shows a 2D vertical section 900 along a fracture plane 903 that shows an elliptical fracture 904 and cross-section of grid cells 902 intersected by the fracture plane 903.

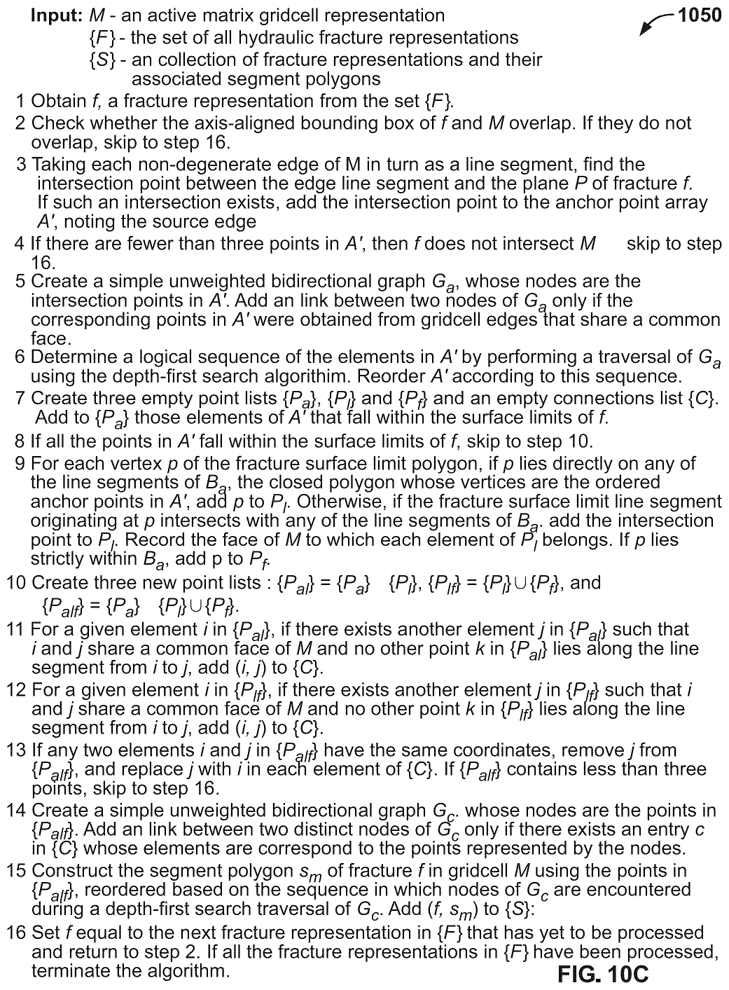

The anchor points are determined by solving a plane and line segment intersection problem. If there are fewer than three fracture plane gridcell anchor points, the fracture does not intersect the gridcell the—procedure advances to the next fracture in the input dataset. If there are three or more fracture plane gridcell anchor points and all the fracture plane anchor points fall within the polygon describing the fracture surface limit, then the perimeter coordinates of the fracture segment are given by the fracture plane anchor points. For example, FIG. 10A shows a graphic 1000 that shows fracture segment perimeter coordinates for gridcell Mₐ of vertical section 900 shown in FIG. 9.

If there are three or more fracture plane gridcell anchor points and at least one of the fracture plane anchor points falls outside the polygon describing the fracture surface limit, then the perimeter coordinates of the fracture segment is given by a properly ordered combination of the fracture plane anchor points that fall within the fracture limit polygon. For example, FIG. 10B shows fracture segment perimeter coordinates for gridcell M_{b} of vertical section 900 shown in FIG. 9 including fracture plane anchor points 1022. Fracture plane anchor points 1022 are the points at which the fracture surface limit polygon line segments intersect with the line segments between fracture plane gridcell anchor points 1024, and the fracture limit polygon vertices 1026 that lie strictly within the area defined by the fracture plane gridcell anchor points 1024. An example of the second algorithm for fracture segment determination is shown as pseudo-code 1050 in FIG. 10c.

Some conventional techniques take the elements of {P_{f}}, that is the fracture plane gridcell anchor points 1024, to be points at which the fracture surface limit line segments intersect with gridcell faces. They determine these points from solving a 3D plane and line segment intersection problem. While this is valid, this approach can be numerically unstable, especially with short fracture surface limit polygon line segments. Note that short fracture surface limit polygon line segments are required to better mimic curvilinear fracture outlines typically encountered in practice. Moreover, these conventional techniques need to explicitly account for the fact that gridcell faces may be biplanar, which unnecessarily complicates their algorithm.

Implementations according to the present disclosure avoid these issues by taking the elements of {P_{f}} to be points at which the fracture surface limit line segments intersect with perimeter of the gridcell on the fracture plane as defined by the anchor points. These points are determined by solving a simple line segments intersection problem, rather than a 3D plane and line segment intersection problem.

Since each active matrix gridcell's intersection with hydraulic fractures is determined independently, the second algorithm can be executed for multiple matrix gridcells concurrently, speeding up processing time. Once completed for all active matrix gridcells, fracture segment adjacencies and the common interface area between adjacent fracture segments can be established. For regular Cartesian grids, this is straight forward because host matrix gridcell (and thus fracture segment) adjacency may easily be established in grid IJK coordinate space. For 3D corner-point grids, fracture segment adjacency cannot be reliably established in grid IJK coordinate space due to layer pinch-outs and faulting typically associated with corner-point grid. Moreover, null, degenerate and irregular corner-point gridcells further complicates determination of fracture segment adjacencies and calculation of common interface area between adjacent fracture segments in corner-point grids.

To solve these issues, the third algorithm is introduced. For example, the third algorithm reliably determines whether or not two fracture segments, sₙ and sₘ, of the same fracture are adjacent. If they are adjacent, the third algorithm determines the line segments describing the common interface between them. Given that the spatial limits of each fracture segment are defined by a polygon, the task reduces to finding line segments that are common to the bounding polygons of sₙ and sₘ.

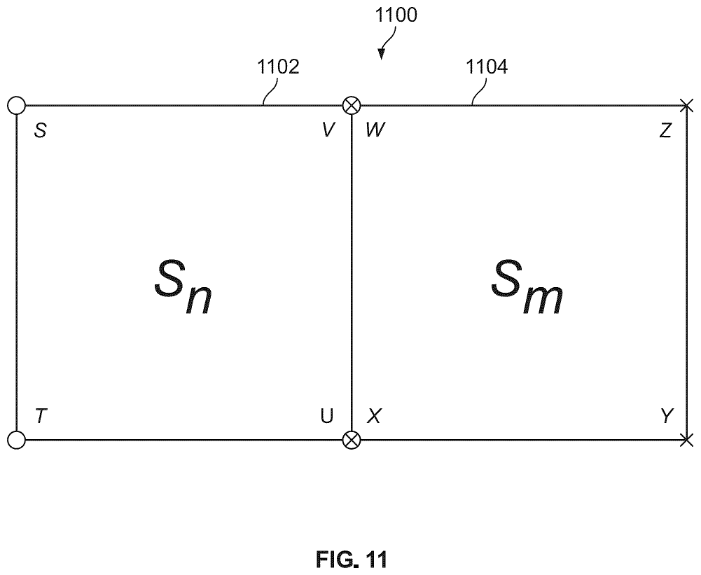

The third algorithm achieves this in two steps. First, the third algorithm identifies those bounding polygon line segments of sₙ that are both collinear and overlapping with bounding polygon line segments of sₘ. This is shown graphically in graphic 1100 in FIG. 11, which shows bounding polygons 1102 and 1104 of two fracture segments sₙ and sₘ. As shown in graphic 1100, line segments ST and YZ are parallel but not collinear. Line segments VS (or TU) and ZW (or XY) are collinear but do not overlap. Line segments UV and WX are collinear and overlap.

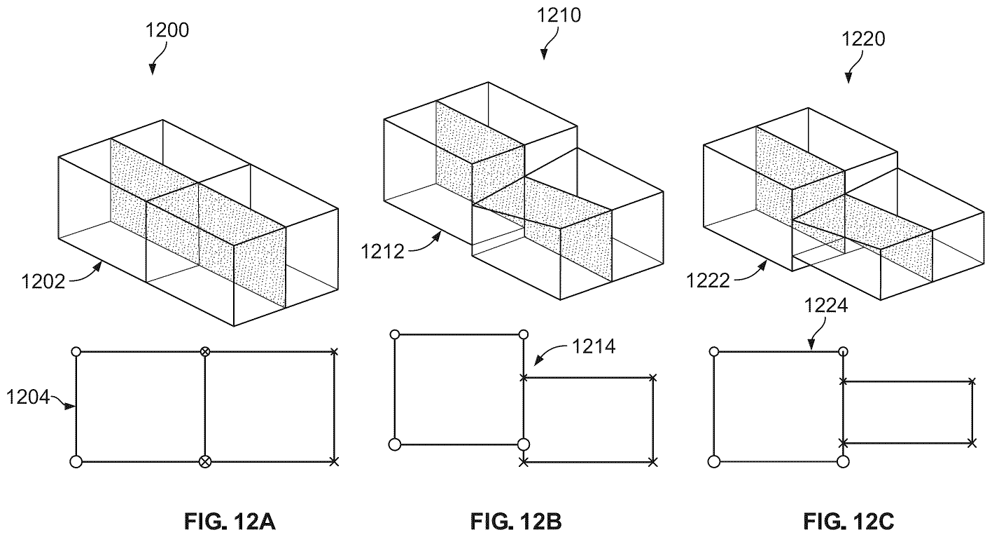

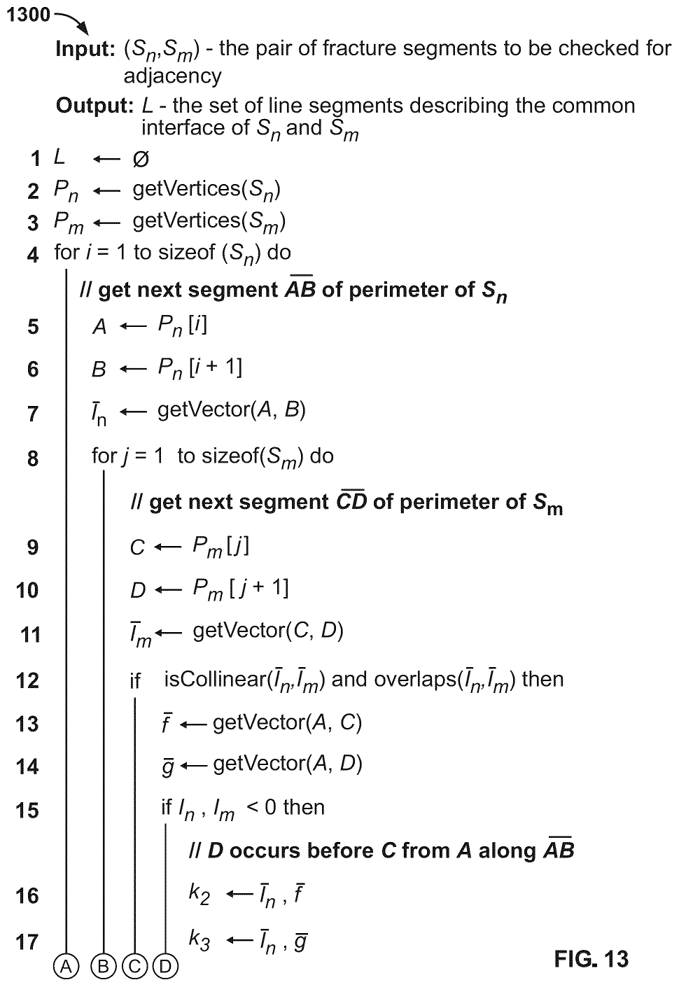

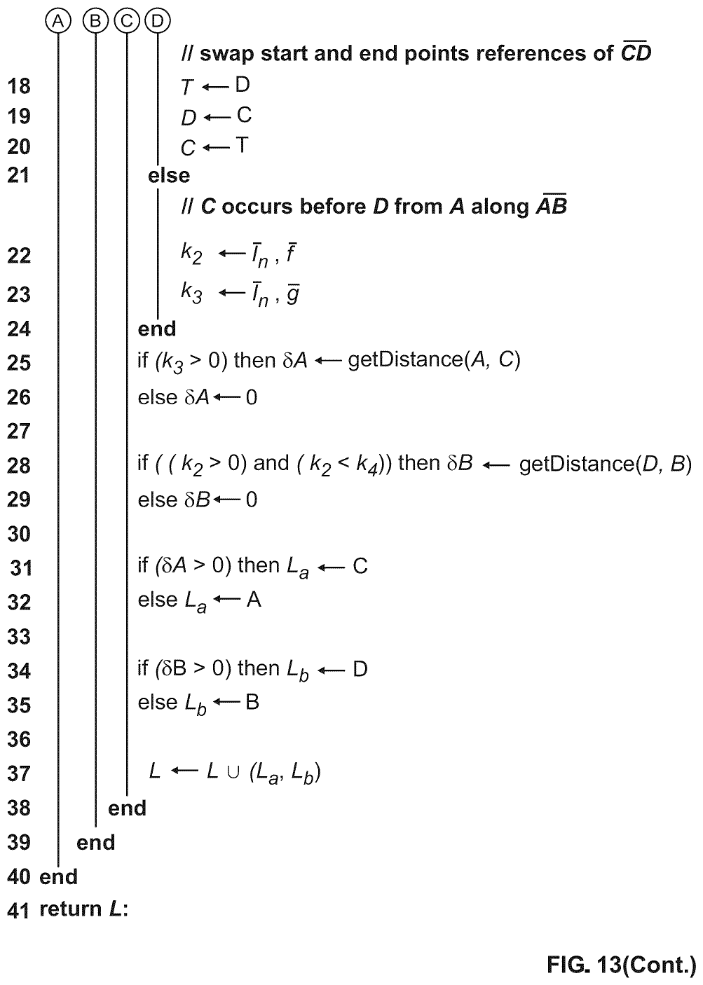

Due to irregularities prevalent in corner-point grids, collinear overlapping bounding line segments may only partially overlap. This is shown graphically in graphics 1200, 1210, and 1220 in FIGS. 12A-12C. Graphic 1200 includes a first example gridcell 1202 with corresponding fracture segments 1204. Graphic 1210 includes a second example gridcell 1212 with corresponding fracture segments 1214. Graphic 1220 includes a third example gridcell 1222 with corresponding fracture segments 1224. This is accounted for in the third algorithm whenever collinear overlapping bounding segments are encountered, an example of which is shown as pseudo-code 1300 in FIG. 13 and provides a determination of fracture segment adjacency and common perimeters.

A line segment l representing each collinear overlapping portion of the perimeters of sₙ and sₘ is included in the returned result set L. If L returns as empty, sₙ and sₘ are not adjacent and a Type II connection transmissibility factor (discussed later herein) is not required between these fracture segments. If L returns as a singleton, sₙ and sₘ are adjacent and their common interface occurs on a gridcell face that has coplanar corner vertices or that is assumed to have coplanar corner vertices (as is implicit in the third algorithm). On the other hand, if L returns containing two elements, sₙ and sₘ are adjacent and their common interface occurs on a biplanar gridcell face.

Method 200 can continue at step 208, which includes performing connection calculations. For example, having determined the intersection points of a given fracture with the matrix grid and the resulting fracture segment adjacencies, the next step is to determine the fracture grid connection transmissibility parameters that are required for a numerical reservoir simulation. There are four connections of interest: a) Type I connection between fracture segment and host matrix gridcell; b) Type II connection between two adjacent fracture segments in the same fracture; c) Type III connection between two intersecting fracture segments (in other words, from two different fractures); and d) Well connection between fracture segment and its penetrating wellbore.

In example aspects, Type I connection transmissibility factor is given as:

$$λ = \frac{α kA}{{d}_{n n c}} . \qquad Eq . 1 ( Hajibeygi et al . , 2011 ; Karimi - Fard et al . , 2004 )$$

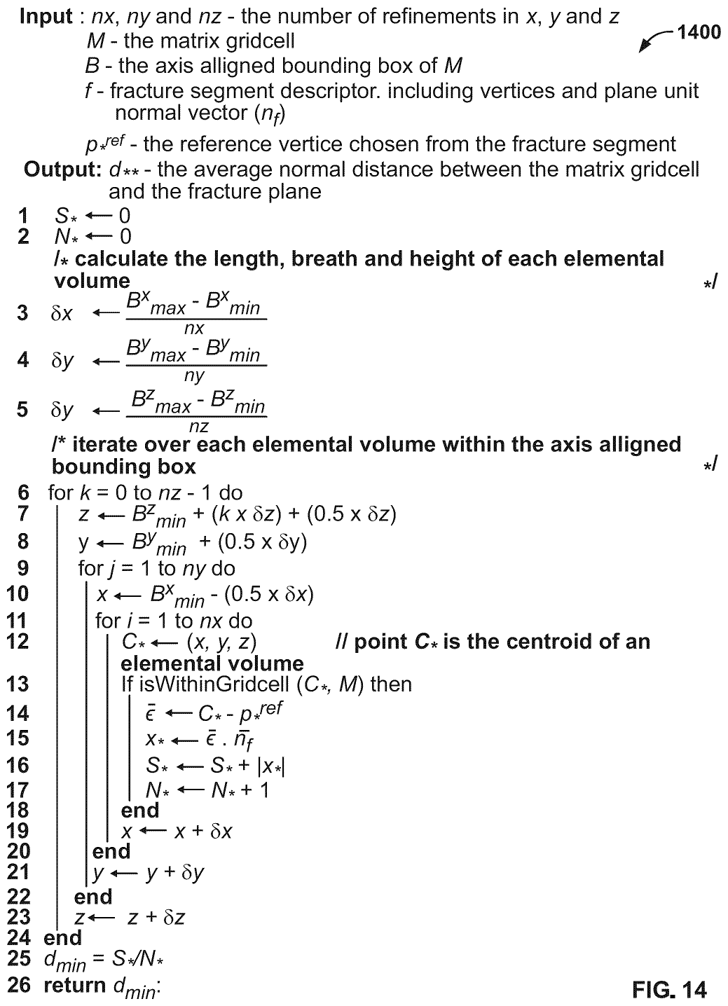

In Eq. 1, d_{nnc}, is the average normal distance between the fracture segment and the connected matrix gridcell. In general, d_{nnc}, can only be obtained from numerical integration. In conventional techniques, this complication is avoided by adopting an analytical solution that is available for very specific situations and apply this solution to more general/typical situations, which sacrifices accuracy. In example implementations according to the present disclosure, a robust numerical integration algorithm is used and is accurate for all situations. This numerical integration method is a fourth algorithm, which is shown as pseudo-code 1400 in FIG. 14 and provides a numerical estimation of d_{nnc}, for Type I connections.

In example aspects, Type II connection transmissibility factor is given as:

$$λ = \frac{{k}_{a} {A}_{f}}{\vert {\vec{d}}_{a} \vert} \vec{{n}_{f a}} \cdot {{u}_{ca}}^{⟶} . \qquad Eq . 2 ( Karimi - Fard et al . , 2004 )$$

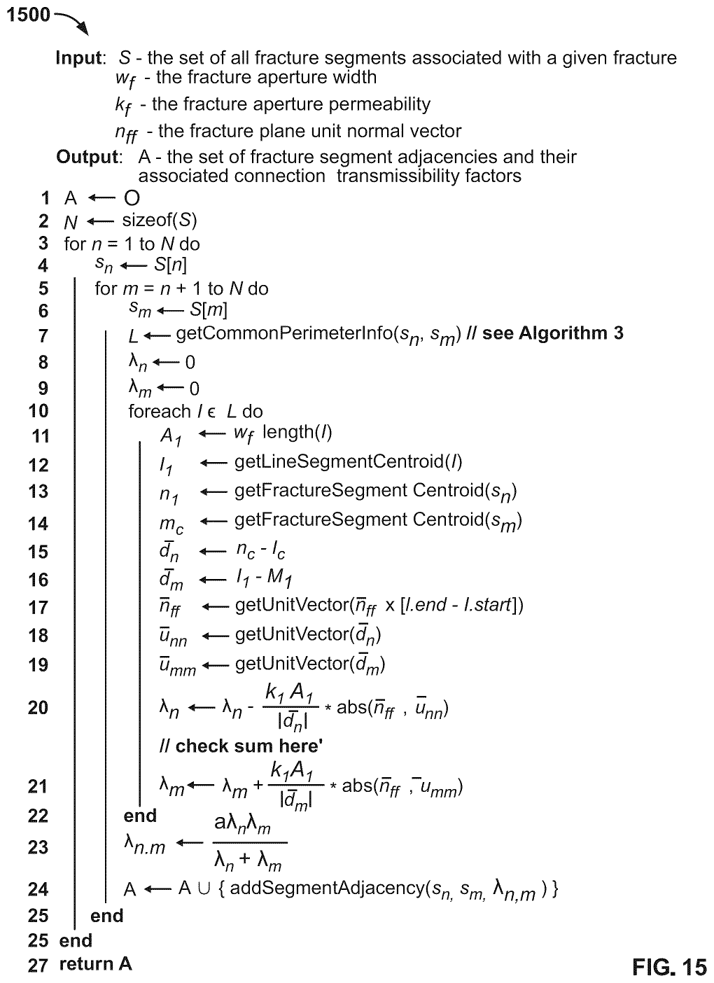

A fifth algorithm is used to determine Type II connection transmissibility factors based on Eq. 2 and is shown as pseudo-code 1500 in FIG. 15.

Method 200 can continue at step 210, which includes setting up the connections. This step includes hydraulic fracture activation and deactivation. For example, in practice, wells may be drilled and put onstream without hydraulic fractures and may only be hydraulically fractured later in their life. Like with other grid based hydraulic fracture modeling methods, embedded discrete fracture modeling can require setup of the embedded fracture grid prior to the start of reservoir simulation. This means that the hydraulically fractured wells in the simulation will have an embedded discrete fractures setup from the beginning of the simulation regardless of the time the fracture actually came into effect. If this is not addressed, the EDFM model 320 could misrepresent the actual well/reservoir performance and fluid flow dynamics due to the embedded discrete fracture being present and active in the reservoir simulation in periods when the actual hydraulic fracture is not present and active in the actual reservoir.

Example implementations according to the present disclosure address this issue through the use of time dependent adjustment factors. The adjustment factor is chosen as either unity or an infinitesimally small number close to zero, depending on whether the modeled hydraulic fracture is to be activated or deactivated. The adjustment factor can be used to scale the calculated well connection transmissibility factor for the well connection between fracture segment and its penetrating wellbore. The scaled well connection transmissibility factor, rather than the originally calculated value, is what is then specified in the recurrent section of the simulation deck for the well.

If a change is needed to the active state of the hydraulic fracture for a given well in the simulation, all that is needed is to re-specify a new, appropriately adjusted/scaled well connection transmissibility factor for the well connection between fracture segment and its penetrating wellbore. Since the time varying state (active or inactive) of the fracture is known prior to start of simulation, the required adjustments can be predetermined during the EDFM preprocessing step so that the EDFM model 320 is correctly setup to reflect the actual active/inactive state of the hydraulic fracture. This approach allows an effective connection (in other words, activation) or disconnection (in other words, deactivation) of a hydraulic fracture to or from a well at any point during the course of the simulation, even though the embedded fracture grid is setup prior to the start of simulation.

Method 200 can continue at step 212, which includes performing a reservoir simulation (with the EDFM model according to the steps 202-210). Performing the simulation validates the EDFM model and, for this disclosure, several different hydraulic fracture well cases were simulated using: (1) a local grid refinement (LGR) method, and (2) the described EDFM formulation of the present disclosure. The results of the simulation were compared in terms of result accuracy and simulation runtime efficiency.

### Example Simulation 1—Regular Grid

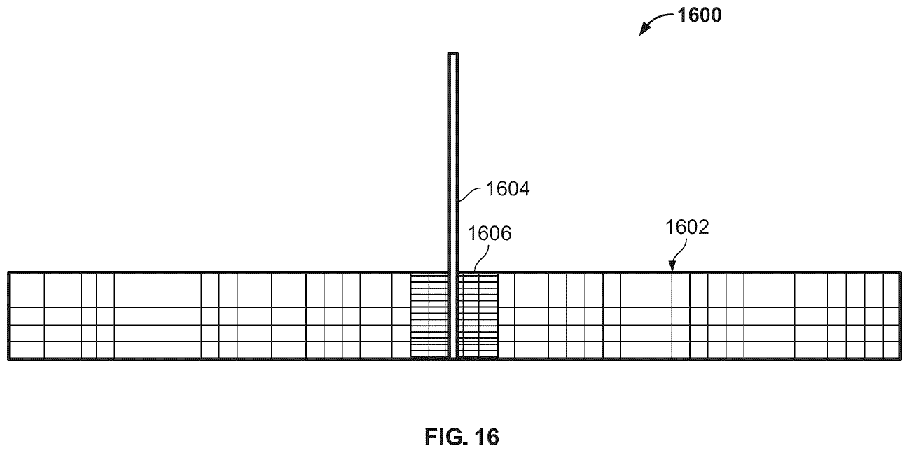

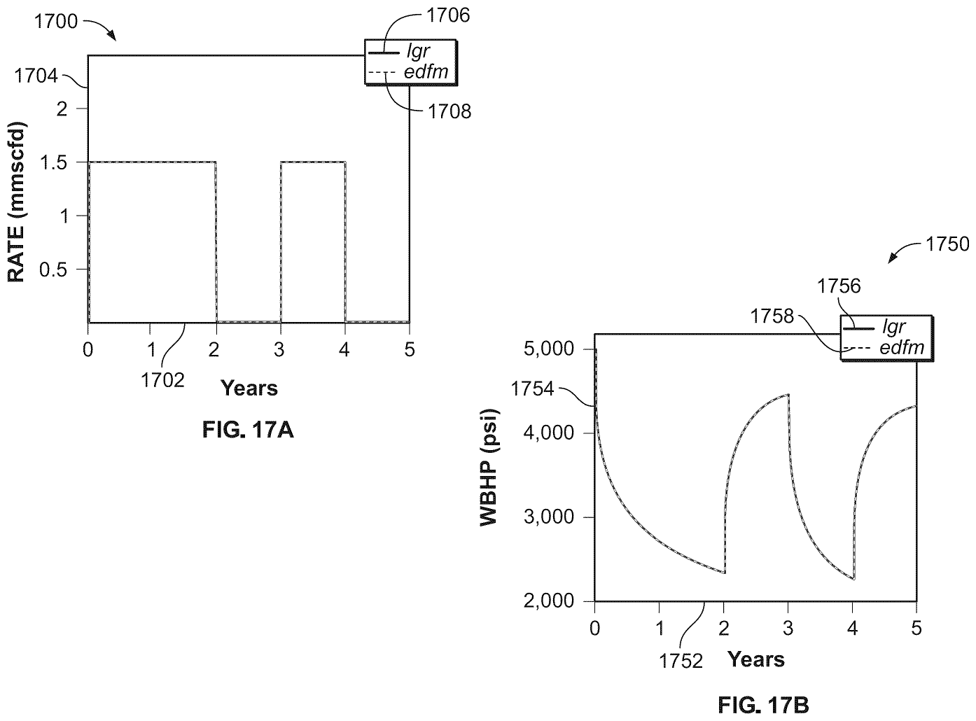

This example considers a homogeneous tight gas reservoir with one fully penetrating vertical well with bi-wing fracture in a regular simulation grid as shown in the graphic 1600 of FIG. 16, which shows the grid 1602, the one fully penetrating vertical well 1604, and the bi-wing fracture 1606. The resulting gas rate and well bottom-hole pressure profiles are shown in graphs 1700 and 1750, respectively, of FIGS. 17A and 17B. Graph 1700 includes x-axis 1702 (time, in years) and y-axis 1704 (gas rate, in mmscfd). The LGR curve 1706 and EDFM curve 1708 are in good agreement for gas rate. Graph 1750 includes x-axis 1752 (time, in years) and y-axis 1754 (well bottom-hole pressure, in psi). The LGR curve 1756 and EDFM curve 1758 are in good agreement for pressure as well.

### Example Simulation 2—Regular Grid

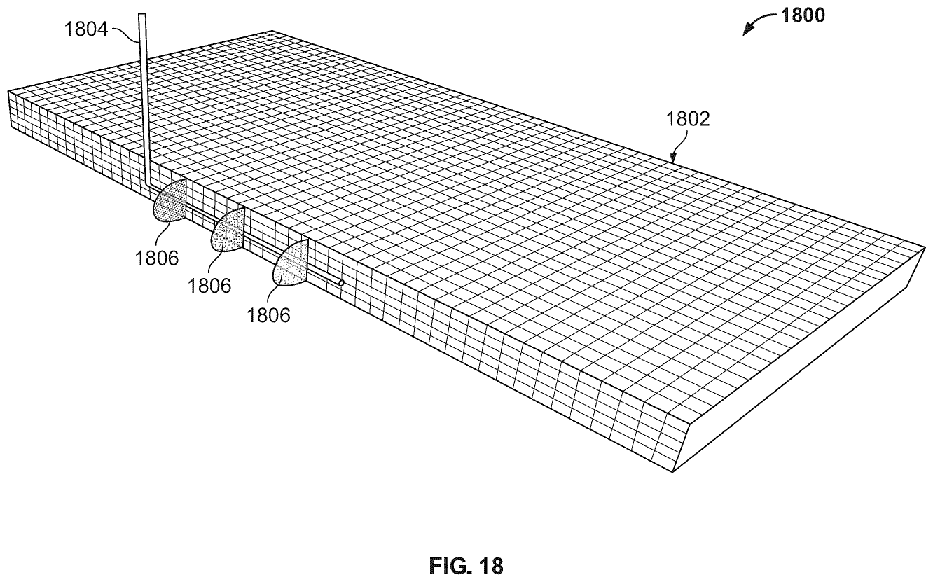

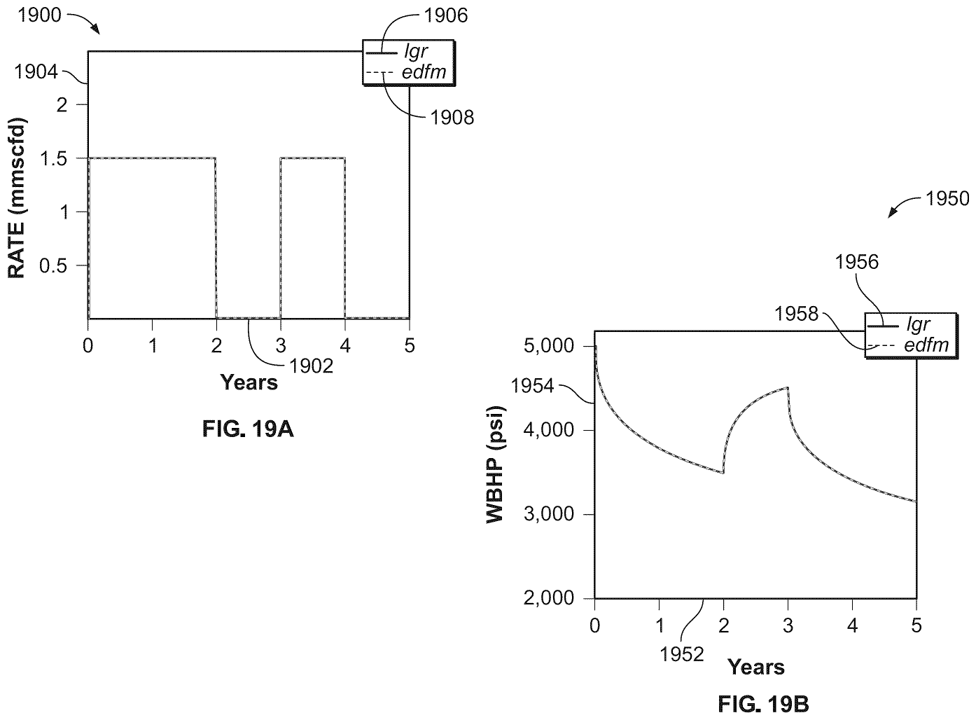

This example considers a homogeneous tight gas reservoir with one horizontal multistage fracture well in a regular simulation grid as shown in the graphic 1800 of FIG. 18, which shows the grid 1802, the one horizontal multistage fracture well 1804, and the fracture stages 1806. The resulting gas rate and well bottom-hole pressure profiles are shown in graphs 1900 and 1950, respectively, of FIGS. 19A and 19B. Graph 1900 includes x-axis 1902 (time, in years) and y-axis 1904 (gas rate, in mmscfd). The LGR curve 1906 and EDFM curve 1908 are in good agreement for gas rate. Graph 1950 includes x-axis 1952 (time, in years) and y-axis 1954 (well bottom-hole pressure, in psi). The LGR curve 1956 and EDFM curve 1958 are in good agreement for pressure as well.

### Example Simulation 3—Complex Grid

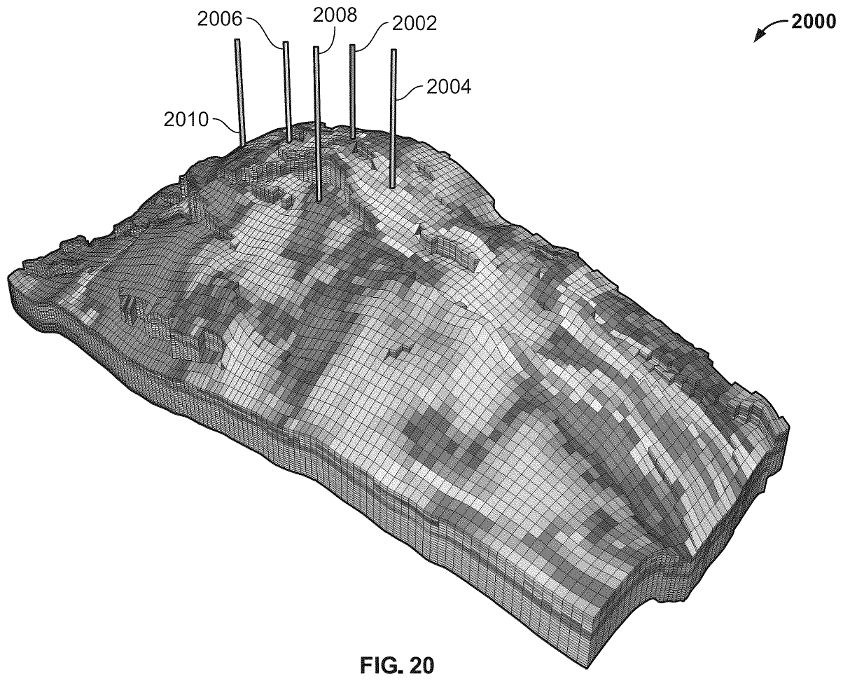

This example considers heterogeneous tight gas reservoir with multiple (5) wells having different types of fractures in a complex corner-point simulation grid as shown in the graphic 2000 of FIG. 20. Here, the five wells in graphic 200 are: well #1 2002, well #2 2004, well #3 2006, well #4 2008, and well #2010.

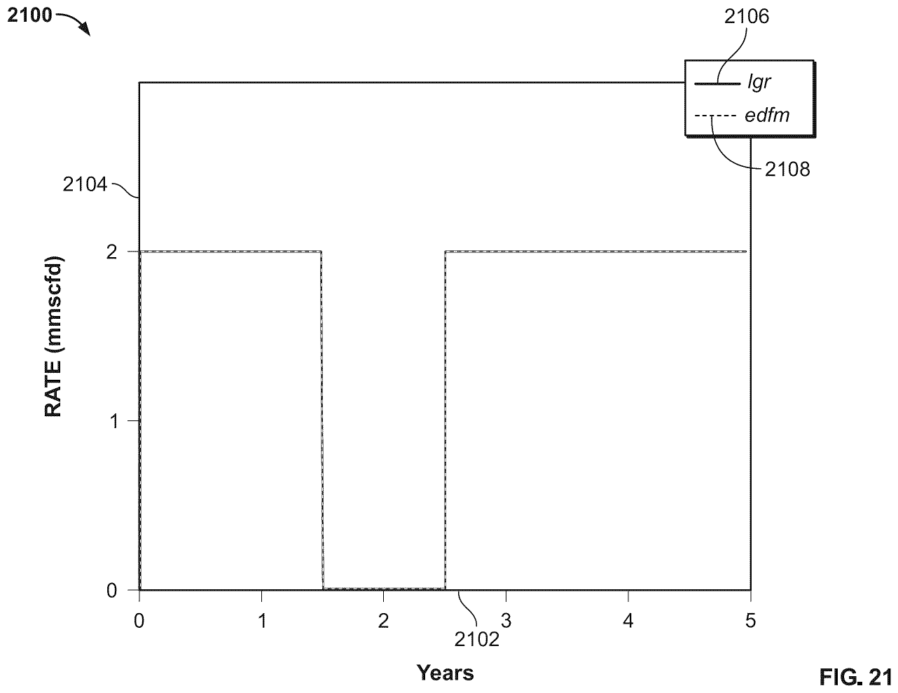

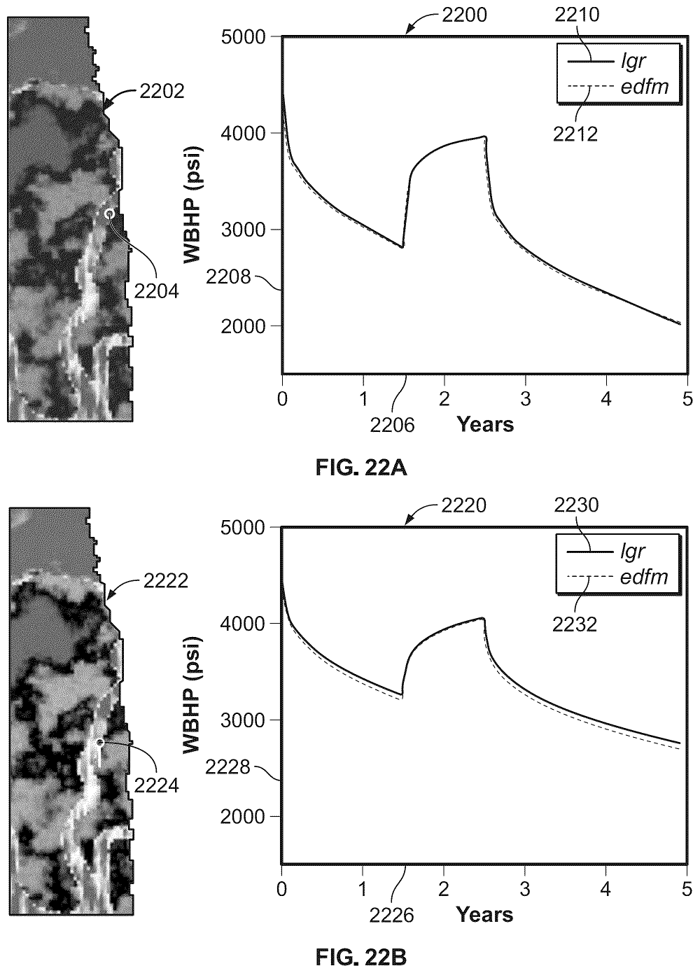

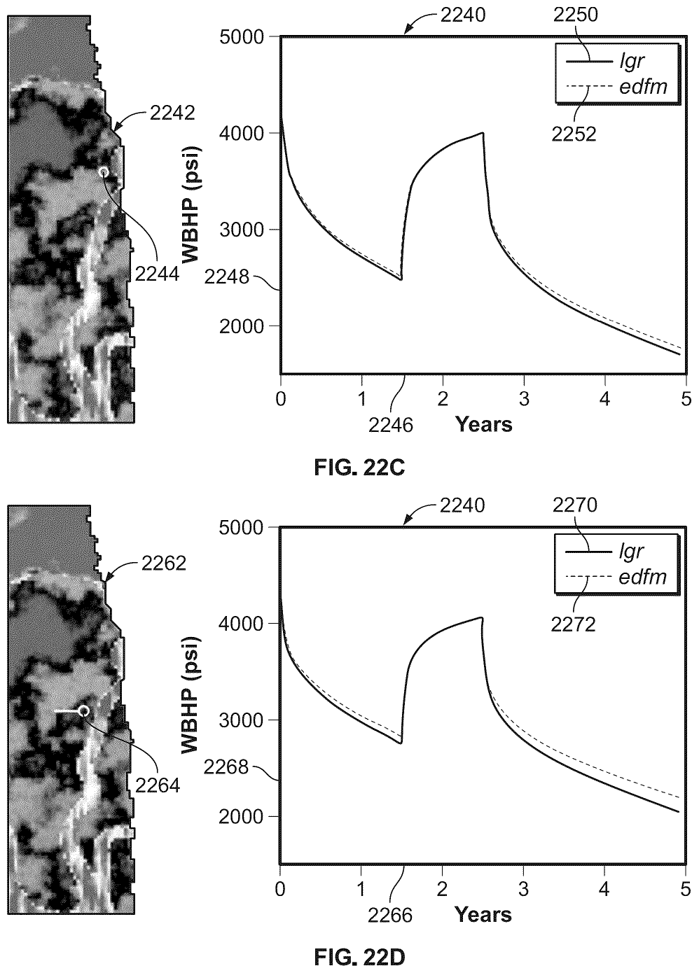

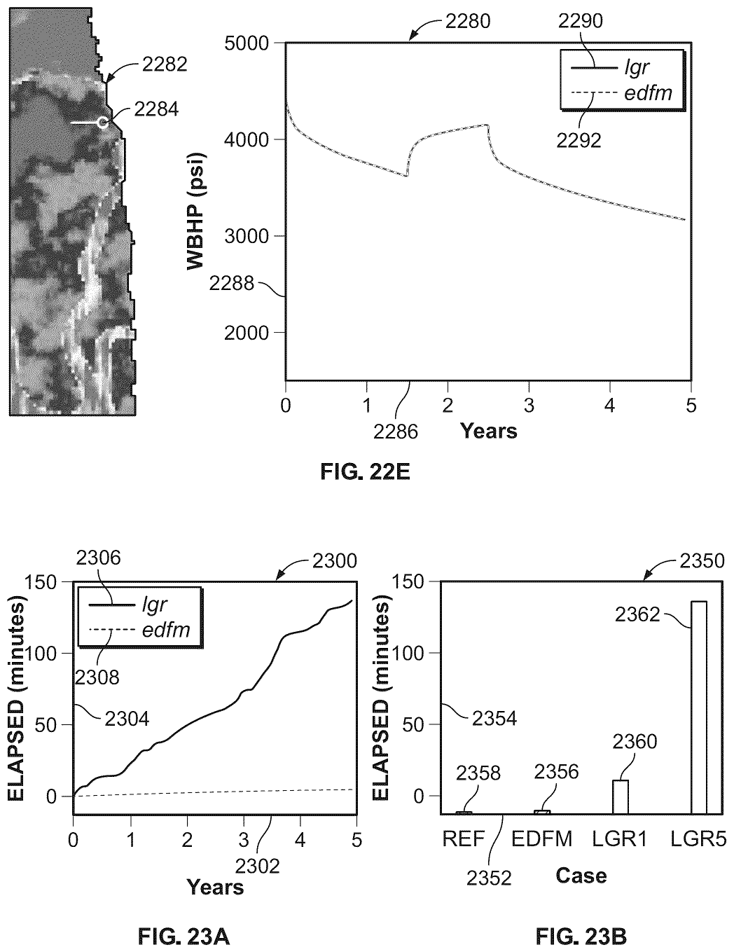

The gas rate profile imposed on each of the active five wells of this simulation is shown in graph 2100 of FIG. 21. Graph 2100 includes x-axis 2002 (time, in years) and y-axis 2004 (gas rate, in mmscfd) with LCR curve 2106 and EDFM curve 2108. The resulting well bottom-hole pressure profiles for the five wells are shown in graphs 2200, 2220, 2240, 2260, and 2280, respectively, of FIGS. 22A-22E.

Graph 2200 describes well bottom hole pressure of, and accompanying 2D map 2202 shows a location of, well #1 2204 in the five-well set. Graph 2200 includes x-axis 2206 (time, in years) and y-axis 2208 (well bottom-hole pressure, in psi). The LGR curve 2210 and EDFM curve 2212 are in good agreement for pressure for well #1 2204.

Graph 2220 describes well bottom hole pressure of, and accompanying 2D map 2222 shows a location of, well #2 2224 in the five-well set. Graph 2220 includes x-axis 2226 (time, in years) and y-axis 2228 (well bottom-hole pressure, in psi). The LGR curve 2230 and EDFM curve 2232 are in good agreement for pressure for well #2 2224.

Graph 2240 describes well bottom hole pressure of, and accompanying 2D map 2242 shows a location of, well #3 2244 in the five-well set. Graph 2240 includes x-axis 2246 (time, in years) and y-axis 2248 (well bottom-hole pressure, in psi). The LGR curve 2250 and EDFM curve 2252 are in good agreement for pressure for well #3 2244.

Graph 2260 describes well bottom hole pressure of, and accompanying 2D map 2262 shows a location of, well #4 2264 in the five-well set. Graph 2260 includes x-axis 2266 (time, in years) and y-axis 2268 (well bottom-hole pressure, in psi). The LGR curve 2270 and EDFM curve 2272 are in good agreement for pressure for well #4 2264.

Graph 2280 describes well bottom hole pressure of, and accompanying 2D map 2282 shows a location of, well #5 2284 in the five-well set. Graph 2280 includes x-axis 2286 (time, in years) and y-axis 2288 (well bottom-hole pressure, in psi). The LGR curve 2290 and EDFM curve 2292 are in good agreement for pressure for well #5 2284.

As shown in the previously described figures related to Examples #1-3, the EDFM simulation results according to the present disclosure are in good agreement with the conventional LGR results. However, when simulation runtime efficiency is taken into account, it is clear that the example implementations of the EDFM approach according to the present disclosure is far more efficient than the LGR method. This is particularly true as the number of wells requiring LGR increase. For example, FIGS. 23A and 23B are graphs 2300 and 2350 that show reservoir simulation time comparisons between the LGR approach and the EDFM approach of the present disclosure. Graph 2300 shows a time required to complete the reservoir simulation for both the LGR approach and the EDFM approach based on a number of simulated years. Graph 2300 includes x-axis 2302 (simulation time, in years) and y-axis 2304 (runtime of simulation, in minutes). As shown, the EDFM curve 2308 is fairly flat even as well production simulation years increase, while the LGR curve 2306 increases steadily.

Graph 2350 shows a time required to complete the reservoir simulation for both the LGR approach and the EDFM approach based on a number of simulated years for Examples #1-3 as well as a reference case. Graph 2350 includes x-axis 2352 (simulation time, in years) and y-axis 2354 (runtime of simulation, in minutes). In this example, the EDFM bar 2356 is the elapsed run time for Example #3, as is the LGR bar 2362. In comparison, the LGR bar 2358 is the elapsed run time for the reference case of a reservoir without hydraulically fractured wells, and the LGR bar 2360 is the elapsed run time for Example #1. As these graphs show, in large gas reservoirs with hundreds of hydraulic fractured wells, the computational overhead associated with the LGR method becomes overwhelming to the point that the LGR method is rendered unviable for field-scale simulation. In contrast, the EDFM formulation of the present disclosure remains viable for such cases.

Method 200 can continue at step 212, which includes outputting reservoir simulation data, for example, to a graphical user interface of a control system that implements method 200. For example, graphics shown in FIGS. 3B and 16 through 23B can be output to a graphical user interface for analysis by an operator.

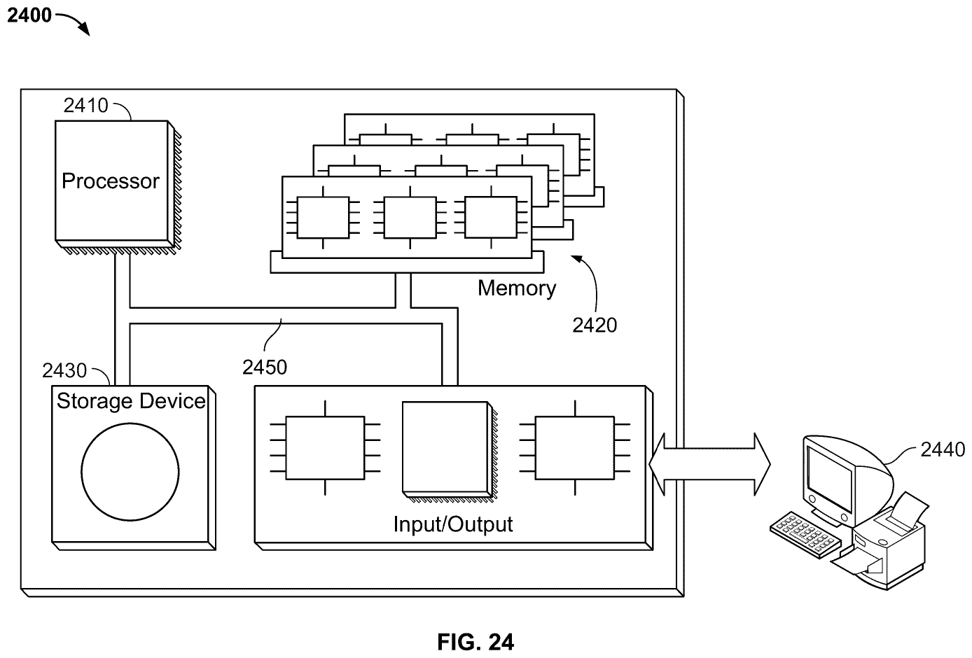

FIG. 24 shows a schematic drawing of a control system 2400 that can be used to build and execute a wellbore model and a reservoir simulator according to the present disclosure. Some or all of the example control system 2400 can be implemented as cloud-based system and/or service, alone or in combination with other portions of the example control system 2400 that can be implemented to execute. The controller 2400 is intended to include various forms of digital computers, such as printed circuit boards (PCB), processors, digital circuitry, or otherwise. Additionally, the system can include portable storage media, such as, Universal Serial Bus (USB) flash drives. For example, the USB flash drives may store operating systems and other applications. The USB flash drives can include input/output components, such as a wireless transmitter or USB connector that may be inserted into a USB port of another computing device.

The controller 2400 includes a processor 2410, a memory 2420, a storage device 2430, and an input/output device 2440. Each of the components 2410, 2420, 2430, and 2440 are interconnected using a system bus 2450. The processor 2410 is capable of processing instructions for execution within the controller 2400. The processor may be designed using any of a number of architectures. For example, the processor 2410 may be a CISC (Complex Instruction Set Computers) processor, a RISC (Reduced Instruction Set Computer) processor, or a MISC (Minimal Instruction Set Computer) processor.

In one implementation, the processor 2410 is a single-threaded processor. In another implementation, the processor 2410 is a multi-threaded processor. The processor 2410 is capable of processing instructions stored in the memory 2420 or on the storage device 2430 to display graphical information for a user interface on the input/output device 2440.

The memory 2420 stores information within the control system 2400. In one implementation, the memory 2420 is a computer-readable medium. In one implementation, the memory 2420 is a volatile memory unit. In another implementation, the memory 2420 is a non-volatile memory unit.

The storage device 2430 is capable of providing mass storage for the controller 2400. In one implementation, the storage device 2430 is a computer-readable medium. In various different implementations, the storage device 2430 may be a floppy disk device, a hard disk device, an optical disk device, a tape device, flash memory, a solid state device (SSD), or a combination thereof.

The input/output device 2440 provides input/output operations for the controller 2400. In one implementation, the input/output device 2440 includes a keyboard and/or pointing device. In another implementation, the input/output device 2440 includes a display unit for displaying graphical user interfaces.

The features described can be implemented in digital electronic circuitry, or in computer hardware, firmware, software, or in combinations of them. The apparatus can be implemented in a computer program product tangibly embodied in an information carrier, for example, in a machine-readable storage device for execution by a programmable processor; and method steps can be performed by a programmable processor executing a program of instructions to perform functions of the described implementations by operating on input data and generating output. The described features can be implemented advantageously in one or more computer programs that are executable on a programmable system including at least one programmable processor coupled to receive data and instructions from, and to transmit data and instructions to, a data storage system, at least one input device, and at least one output device. A computer program is a set of instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

Suitable processors for the execution of a program of instructions include, by way of example, both general and special purpose microprocessors, and the sole processor or one of multiple processors of any kind of computer. Generally, a processor will receive instructions and data from a read-only memory or a random access memory or both. The essential elements of a computer are a processor for executing instructions and one or more memories for storing instructions and data. Generally, a computer will also include, or be operatively coupled to communicate with, one or more mass storage devices for storing data files; such devices include magnetic disks, such as internal hard disks and removable disks; magneto-optical disks; and optical disks. Storage devices suitable for tangibly embodying computer program instructions and data include all forms of non-volatile memory, including by way of example semiconductor memory devices, such as EPROM, EEPROM, solid state drives (SSDs), and flash memory devices; magnetic disks such as internal hard disks and removable disks; magneto-optical disks; and CD-ROM and DVD-ROM disks. The processor and the memory can be supplemented by, or incorporated in, ASICs (application-specific integrated circuits).

To provide for interaction with a user, the features can be implemented on a computer having a display device such as a CRT (cathode ray tube) or LCD (liquid crystal display) or LED (light-emitting diode) monitor for displaying information to the user and a keyboard and a pointing device such as a mouse or a trackball by which the user can provide input to the computer. Additionally, such activities can be implemented via touchscreen flat-panel displays and other appropriate mechanisms.

The features can be implemented in a control system that includes a back-end component, such as a data server, or that includes a middleware component, such as an application server or an Internet server, or that includes a front-end component, such as a client computer having a graphical user interface or an Internet browser, or any combination of them. The components of the system can be connected by any form or medium of digital data communication such as a communication network. Examples of communication networks include a local area network (“LAN”), a wide area network (“WAN”), peer-to-peer networks (having ad-hoc or static members), grid computing infrastructures, and the Internet.

While this specification contains many specific implementation details, these should not be construed as limitations on the scope of any inventions or of what may be claimed, but rather as descriptions of features specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products.

A number of implementations have been described. Nevertheless, it will be understood that various modifications may be made without departing from the spirit and scope of the disclosure. For example, example operations, methods, or processes described herein may include more steps or fewer steps than those described. Further, the steps in such example operations, methods, or processes may be performed in different successions than that described or illustrated in the figures. Accordingly, other implementations are within the scope of the following claims.

What is claimed is:

1. A computer-implemented method of modeling a reservoir, comprising:
identifying or inputting well and reservoir model parameters into a control system;
calculating, with the control system, one or more hydraulic fracture limits of one or more hydraulic fractures in the reservoir model;
determining, with the control system, one or more fracture segments;
performing, with the control system, connection calculations based on the one or more hydraulic fracture limits and one or more fracture segments;
setting up, with the control system, connections between the one or more hydraulic fractures and a matrix grid of the reservoir model;
performing, with the control system, a reservoir simulation; and
outputting, with the control system, reservoir simulation data from the reservoir simulation.

2. The computer-implemented method of claim 1, wherein the reservoir model comprises an embedded discrete fracture modeling (EDFM) reservoir model that comprises a matrix computational domain, a spare mirror fracture computational domain, and an inactive zone that separates the matrix computational domain and the spare mirror fracture computational domain.

3. The computer-implemented method of claim 1, wherein calculating the one or more hydraulic fracture limits of one or more hydraulic fractures in the reservoir model comprises calculating, for each hydraulic fracture, a fracture surface limit and a fracture wing adjustment based on the well and reservoir model parameters including well trajectory information and fracture geometry information.

4. The computer-implemented method of claim 1, wherein determining the one or more fracture segments comprises executing, with the control system, a multi algorithmic framework.

5. The computer-implemented method of claim 4, wherein executing the multi algorithmic framework comprises:
executing, with the control system, a first algorithm to determine a fracture segments processing framework;
executing, with the control system, a second algorithm to determine fracture segments; and
executing, with the control system, a third algorithm to determine fracture segment adjacency and common perimeter determination.

6. The computer-implemented method of claim 5, wherein performing the connection calculations comprises:
executing, with the control system, a fourth algorithm to determine a numerical estimation of one or more average normal distances between a fracture segment and a connected matrix gridcell of the reservoir model; and
executing, with the control system, a fifth algorithm to determine one or more fracture type connection transmissibility factors.

7. The computer-implemented method of claim 1, wherein performing the reservoir simulation comprises determining, with the control system, hydrocarbon fluid production rate and well bottom hole pressure for each well in the reservoir model.

8. A computing system, comprising:
one or more memory modules configured to store well and reservoir model parameters;
one or more hardware processors communicably coupled to the one or more memory modules and configured to execute instructions stored on the one or more memory modules to perform operations comprising:
calculating one or more hydraulic fracture limits of one or more hydraulic fractures in the reservoir model;
determining one or more fracture segments;
performing connection calculations based on the one or more hydraulic fracture limits and one or more fracture segments;
setting up connections between the one or more hydraulic fractures and a matrix grid of the reservoir model;
performing a reservoir simulation; and
outputting reservoir simulation data from the reservoir simulation.

9. The computing system of claim 8, wherein the reservoir model comprises an embedded discrete fracture modeling (EDFM) reservoir model that comprises a matrix computational domain, a spare mirror fracture computational domain, and an inactive zone that separates the matrix computational domain and the spare mirror fracture computational domain.

10. The computing system of claim 8, wherein the operation of calculating the one or more hydraulic fracture limits of one or more hydraulic fractures in the reservoir model comprises calculating, for each hydraulic fracture, a fracture surface limit and a fracture wing adjustment based on the well and reservoir model parameters including well trajectory information and fracture geometry information.

11. The computing system of claim 8, wherein the operation of determining the one or more fracture segments comprises executing a multi algorithmic framework.

12. The computing system of claim 11, wherein the operation of executing the multi algorithmic framework comprises:
executing a first algorithm to determine a fracture segments processing framework;
executing a second algorithm to determine fracture segments; and
executing a third algorithm to determine fracture segment adjacency and common perimeter determination.

13. The computing system of claim 12, wherein the operation of performing the connection calculations comprises:
executing a fourth algorithm to determine a numerical estimation of one or more average normal distances between a fracture segment and a connected matrix gridcell of the reservoir model; and
executing a fifth algorithm to determine one or more fracture type connection transmissibility factors.

14. The computing system of claim 8, wherein the operation of performing the reservoir simulation comprises determining hydrocarbon fluid production rate and well bottom hole pressure for each well in the reservoir model.

15. An apparatus comprising a tangible, non-transitory computer readable memory comprising instructions for causing one or more processors to perform operations comprising:
identifying well and reservoir model parameters;
calculating one or more hydraulic fracture limits of one or more hydraulic fractures in the reservoir model;
determining one or more fracture segments;
performing connection calculations based on the one or more hydraulic fracture limits and one or more fracture segments;
setting up connections between the one or more hydraulic fractures and a matrix grid of the reservoir model;
performing a reservoir simulation; and
outputting reservoir simulation data from the reservoir simulation.

16. The apparatus of claim 15, wherein the reservoir model comprises an embedded discrete fracture modeling (EDFM) reservoir model that comprises a matrix computational domain, a spare mirror fracture computational domain, and an inactive zone that separates the matrix computational domain and the spare mirror fracture computational domain.

17. The apparatus of claim 15, wherein the operation of calculating the one or more hydraulic fracture limits of one or more hydraulic fractures in the reservoir model comprises calculating, for each hydraulic fracture, a fracture surface limit and a fracture wing adjustment based on the well and reservoir model parameters including well trajectory information and fracture geometry information.

18. The apparatus of claim 15, wherein the operation of determining the one or more fracture segments comprises executing a multi algorithmic framework.

19. The apparatus of claim 18, wherein the operation of executing the multi algorithmic framework comprises:
executing a first algorithm to determine a fracture segments processing framework;
executing a second algorithm to determine fracture segments; and
executing a third algorithm to determine fracture segment adjacency and common perimeter determination.

20. The apparatus of claim 19, wherein the operation of performing the connection calculations comprises:
executing a fourth algorithm to determine a numerical estimation of one or more average normal distances between a fracture segment and a connected matrix gridcell of the reservoir model; and
executing a fifth algorithm to determine one or more fracture type connection transmissibility factors.

21. The apparatus of claim 15, wherein the operation of performing the reservoir simulation comprises determining hydrocarbon fluid production rate and well bottom hole pressure for each well in the reservoir model.
